(19) United States
(12) Patent Application Publication
(10) Pub. No.: US 2025/0163561 A1
(43) Pub. Date: May 22, 2025

(54) POLYMER TEMPLATING OF ALPHA-PHASE TANTALUM

(71) Applicant: Lawrence Livermore National Security, LLC, Livermore, CA (US)

(72) Inventor: Loren Daniel Hufty Alegria, San Francisco, CA (US)

(21) Appl. No.: 18/932,381

(22) Filed: Oct. 30, 2024

Related U.S. Application Data
(60) Provisional application No. 63/595,158, filed on Nov. 1, 2023.

(51) Int. Cl. C23C 14/00; B32B 15/01; H10N 60/01; H10N 60/83

(52) U.S. Cl. CPC C23C 14/0005; B32B 15/01; B32B 2311/18; B32B 2311/24; H10N 60/01; H10N 60/83

(57) ABSTRACT

A product includes a three-dimensional structure comprising a continuous metallic material. The continuous metallic material includes at least two layers. A first layer of the at least two layers includes a metal and a second layer of the at least two layers includes a transition metal having a body-centered-cubic crystal structure. A method of forming a three-dimensional structure having a continuous metallic material includes forming a polymer template, depositing a seed layer on the polymer template, and depositing a metallic layer on the seed layer. The metallic layer includes a transition metal that is nucleated by the seed layer thereby forming the continuous metallic material having a body-centered-cubic crystal structure.

### RELATED APPLICATIONS

This application claims priority to U.S. Provisional Patent Application No. 63/595,158 filed Nov. 1, 2023, which is herein incorporated by reference.

This invention was made with Government support under Contract No. DE-AC52-07NA27344 awarded by the United States Department of Energy. The Government has certain rights in the invention.

### FIELD OF THE INVENTION

The present invention relates to templating tantalum, and more particularly, this invention relates to polymer templating of alpha-phase tantalum.

### BACKGROUND

Microelectronics and, in particular, superconducting quantum processors increasingly depend upon three-dimensional (3D) metal structures to overcome constraints of purely planar, two-dimensional (2D) microfabrication on low-loss dielectric surfaces (such as sapphire or silicon). The loss typically originates around a large area around the circuit, e.g., the volume around the circuit. Moreover, certain materials cause loss on the surface of the circuit thereby resulting in severely degraded quantum coherence and, ultimately, inoperable circuits. Thus, within superconducting qubit devices, the most common examples of 3D metal structures are airbridges (e.g., free-standing bridges) on very clean simple dielectric surfaces (e.g., sapphire surface, silicon surface, etc.) that allow for electrical pathways to be routed up and over other electrical pathways. Airbridges are currently being used extensively in the superconducting qubit community, and are typically made from high purity aluminum (Al) or titanium (Ti). However, it is critical for the airbridges to be free all sources of loss, such as no residues on the surface, no oxides on the surface, etc.

In order to microfabricate 3D structures such as airbridges, one or more layers of photoresist polymer may be used to readily pattern an arbitrary shape that may be transferred to a metal by depositing a layer of metal on top of the patterned polymer resist and then chemically removing the resist. However, a drawback of this process is the product always includes some carbon-containing residue. An aggressive, well known remover of such residues is a Piranha etch (a solution of sulfuric acid (H₂SO₄) and hydrogen peroxide (H₂O₂)), which can remove all the carbon-containing residue; however, the Piranha etch will also readily dissolve most metals, including Al and Ti.

Moreover, other metals have not been considered for the aforementioned polymer templating processes because making films with high conductivity (e.g., the bcc phase of the tantalum crystal) often requires temperatures in excess of 500° C., which will deteriorate any polymer template structure.

It would be desirable to form a 3D structure of a continuous metallic material having a bcc crystal phase, that is resistant to strong acid etching, via a process such as polymer templating.

### SUMMARY

According to one embodiment, a product includes a three-dimensional structure comprising a continuous metallic material. The continuous metallic material includes at least two layers. A first layer of the at least two layers includes a metal and a second layer of the at least two layers includes a transition metal having a body-centered-cubic crystal structure.

According to another embodiment, a method of forming a three-dimensional structure having a continuous metallic material includes forming a polymer template, depositing a seed layer on the polymer template, and depositing a metallic layer on the seed layer. The metallic layer includes a transition metal that is nucleated by the seed layer thereby forming the continuous metallic material having a body-centered-cubic crystal structure.

Other aspects and advantages of the present invention will become apparent from the following detailed description, which, when taken in conjunction with the drawings, illustrate by way of example the principles of the invention.

### BRIEF DESCRIPTION OF THE DRAWINGS

FIG. 1 is an image of airbridge used for electrical measurement, according to one embodiment.

FIG. 2A is a scanning electron microscope (SEM) image of a top down view of a series of airbridges formed using a method as described herein, according to one embodiment.

FIG. 2B is an SEM of a perspective view of a series of airbridges formed using a method as described herein, according to one embodiment.

FIG. 3 is a flowchart of a method for forming a three-dimensional structure of continuous metallic material, according to one embodiment.

FIG. 4 is a series of images of the deposition of niobium and tantalum, according to one embodiment. Part (a) is side view of 210 nm of tantalum deposited on a thin layer of niobium, and part (b) is a magnified view of the bottom layer showing tantalum deposited onto 2 nm of tantalum.

FIG. 5 is a series of images of a top down view of operations for forming airbridges, according to one embodiment. Part (a) is an image of the forming of a scaffold structure using a polymer resist material, part (b) is an image of reflowing the scaffold structures, and part (c) is an image of defining the scaffold structures.

FIG. 6 illustrates operations of the method, according to one embodiment. Part (a) is image of a top down view of the scaffold formed on a substrate with polymer resist material, part (b) is an image of a top down view of the scaffold structures after reflow, part (c) is a top down view of the structures after addition of the mask layer, part (d) is an image of a side view of the structures after sputtering the metal layers and liftoff, part (e) is an image of a top down view of the substrate and airbridges after liftoff, and part (f) is an image of a top down view of the substrate and airbridges after acid etching.

FIG. 7 depicts images of a series of airbridges on a substrate following acid etching, according to one embodiment. Part (a) is an image of a top down view, and part (b) is an image of a bottom up view.

FIG. 8 is a plot of the resistivity of tantalum films having primarily alpha and beta crystal structures, according to one embodiment.

FIG. 9 depicts the morphology of nucleated and non-nucleated tantalum films, according to one embodiment. Part (a) illustrates a comparison of tantalum films grown by various conditions, part (b) tantalum filaments grown on sapphire substrate, part (c) tantalum filaments on niobium on sapphire substrate, part (d) tantalum filaments on niobium on silicone substrate, and part (e) tantalum filaments on silicone substrate.

### DETAILED DESCRIPTION

The following description is made for the purpose of illustrating the general principles of the present invention and is not meant to limit the inventive concepts claimed herein. Further, particular features described herein can be used in combination with other described features in each of the various possible combinations and permutations.

Unless otherwise specifically defined herein, all terms are to be given their broadest possible interpretation including meanings implied from the specification as well as meanings understood by those skilled in the art and/or as defined in dictionaries, treatises, etc.

It must also be noted that, as used in the specification and the appended claims, the singular forms “a,” “an” and “the” include plural referents unless otherwise specified.

For the purposes of this application, room temperature is defined as in a range of about 20° C. to about 25° C.

As also used herein, the term “about” denotes an interval of accuracy that ensures the technical effect of the feature in question. In various approaches, the term “about” when combined with a value, refers to plus and minus 10% of the reference value. For example, a thickness of about 10 nm refers to a thickness of 10 nm±1 nm, a temperature of about 50° C. refers to a temperature of 50° C.±5° C., etc.

A “nano” dimension or descriptor such as nanoscale, nanoporous, etc. is defined as having a diameter or length (e.g., a pore having an average diameter) less than 1000 nanometers (nm). A “micro” dimension or descriptor such as microscale, microporous, micron-sized, etc. is defined as having a diameter or length (e.g., a pore having an average diameter) less than about 1000 microns (μm).

It is also noted that, as used in the specification and the appended claims, wt. % is defined as the percentage of weight of a particular component relative to the total weight/mass of the mixture. Vol. % is defined as the percentage of volume of a particular compound relative to the total volume of the mixture or compound. Mol. % is defined as the percentage of moles of a particular component relative to the total moles of the mixture or compound. Atomic % (at. %) is defined as a percentage of one type of atom relative to the total number of atoms of a compound.

Unless expressly defined otherwise herein, each component listed in a particular approach may be present in an effective amount. An effective amount of a component means that enough of the component is present to result in a discernable change in a target characteristic of the ink, printed structure, and/or final product in which the component is present, and preferably results in a change of the characteristic to within a desired range. One skilled in the art, now armed with the teachings herein, would be able to readily determine an effective amount of a particular component without having to resort to undue experimentation.

The following description discloses several preferred embodiments for polymer templating of alpha-phase tantalum and/or related systems and methods.

In one general embodiment, a product includes a three-dimensional structure comprising a continuous metallic material. The continuous metallic material includes at least two layers. A first layer of the at least two layers includes a metal and a second layer of the at least two layers includes a transition metal having a body-centered-cubic crystal structure.

In another general embodiment, a method of forming a three-dimensional structure having a continuous metallic material includes forming a polymer template, depositing a seed layer on the polymer template, and depositing a metallic layer on the seed layer. The metallic layer includes a transition metal that is nucleated by the seed layer thereby forming the continuous metallic material having a body-centered-cubic crystal structure.

A list of acronyms used in the description is provided below.
3D three-dimensional
Al aluminum
AM additive manufacturing
bcc body-centered-cubic
C Celsius
H₂O₂ hydrogen peroxide
H₂SO₄ sulfuric acid
Nb niobium
nm nanometer
Ta tantalum
Ti titanium
μm micron
wt. % weight percent
vol. % volume percent

According to various embodiments, a three-dimensional (3D) structure may be formed of a continuous metallic material. The 3D structure is preferably a normal metal at room temperature and becomes a superconductor—a distinct phase of the electrons in the metal—at low temperatures, thereby providing the low-loss levels that are essential for various applications. A continuous metallic material is defined as a material that is free of cracks having a width less than a few nanometers (e.g., 1-2 nanometers). A continuous metallic material may have grain boundaries that are defined as interfaces between regions of different crystal orientations of the metallic material.

According to one embodiment, a product includes a 3D structure comprising a continuous metallic material. The continuous metallic material includes at least two layers where a first layer is a seed layer and a second layer includes a transition metal having a body-centered-cubic (bcc) crystal structure. In various approaches, the metal of the seed layer may be one of the following: titanium (Ti), niobium (Nb), aluminum (Al), etc. Niobium is a transition metal that is a superconductor with a high melting point. The Mohs hardness rating of niobium is similar to titanium. The physical and chemical properties of niobium are similar to tantalum.

In various approaches, the process of forming a suspended structure having low loss levels may include forming a bridge-type structure, a tunnel-like structure, a tent-like structure, a drum-like structure, etc. These structures may be used as micromechanical sensors and resonators. According to one approach, a 3D structure may be formed on a surface of a substrate, e.g., a wafer, that provides a suspended superconducting channel within a circuit. The substrate may be a semiconductor, at all temperatures.

In preferred approaches, the continuous metallic material includes a second layer having a transition metal has a body-centered-cubic (bcc) crystal structure where the structure includes at least 98 vol. % bcc crystal structure. In a preferred approach, the transition metal of the second layer is pure tantalum.

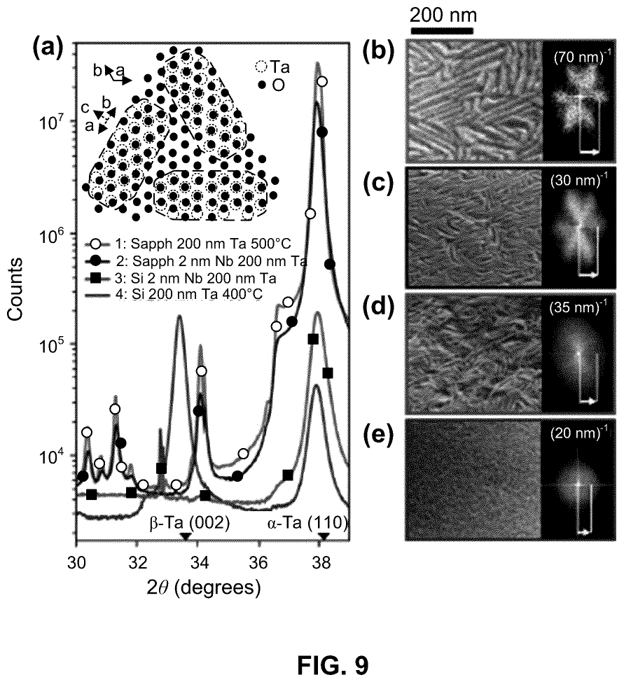

The transition metal tantalum (Ta) can withstand strong etches and has excellent electronic and mechanical properties as a result of which it is used broadly in microelectronics. Moreover, its relatively high superconducting temperature (4.3 K) and superlative surface qualities make it suitable for low-loss superconducting channels, such as those in superconducting qubit processors. In an exemplary approach, the transition metal comprising the continuous metal material includes essentially tantalum (Ta). The purity of Ta may be greater than 98% as inferred quantitatively from XRD data (for example, see parts (b) and (c) of FIG. 9). The crystal structure of Ta may be predominantly (greater than 98 vol. %) a bcc crystal structure, i.e., in the alpha-phase (α-Ta). Moreover, the structure is essentially free of carbon residue.

According to one approach, a 3D structure is suspended on a substrate where the 3D structure has a portion suspended on the substrate. The suspended 3D structure preferably includes continuous metallic material. At least one end of the structure is positioned on the surface of the substrate.

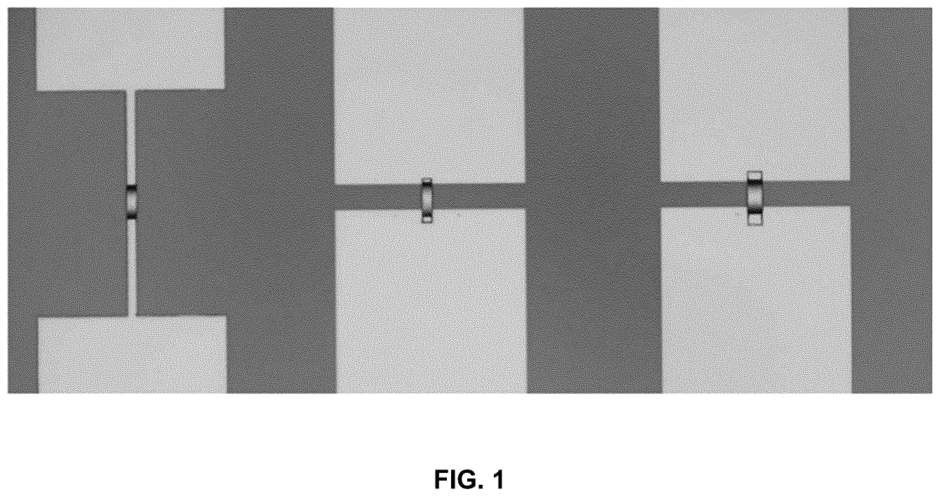

In one approach, the 3D structure is a bridge, such as an airbridge. FIG. 1 depicts a top down view of a series of airbridges that provide low loss superconducting channels on a wafer without adding any detrimental residues to the surfaces. In one example, an airbridge has a portion having an arched shape. The arched shape is positioned between opposite distal ends of the structure, the ends of the structure are positioned on a surface of the substrate.

In one approach, the substrate and structure are essentially free of carbon residue. In one approach, undetectable amounts of organic residue on the substrate and 3D structure may be assessed by visible detection of organic residue on the surfaces of the substrate. Preferably, the 3D structures are visibly clean of organic residues as assessed by visible inspection of images of the 3D structures. Images of the substrate may be used to set bounds of the mass of organic residues present on the substrate before and after acid/peroxide/ultrasonic treatment.

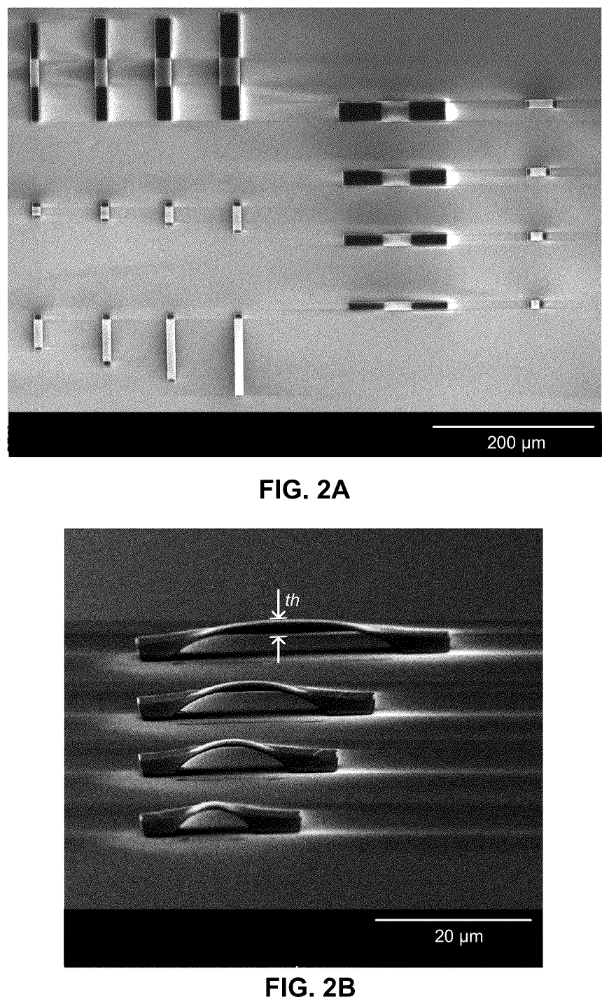

In one example, FIGS. 2A-2B illustrate bridges having various lengths, arches, and ends that represent the feet of the bridge. FIG. 2A is an image of a top down view of a series of airbridges comprised of α-Ta, where the airbridges are on a surface of a wafer without any oxide residues, carbon residues, etc. providing a clean low loss surface of the wafer. The substrate is essentially free of carbon residue. FIG. 2B is an image of a perspective view of a series of airbridges formed where the surface of the airbridge is essentially Ta. The perspective view illustrates the contour of the arch of each bridge showing the feet of the bridge attached to the surface of the substrate.

In one embodiment, the formed 3D structure is a thin structure. The structure has a thickness in a range of greater than 100 nanometers to less than about 2000 nm (2 microns). In some preferred approaches, the structure has a thickness in a range of greater than 100 nm and less than 500 nm. For example, as shown in the airbridges of FIG. 2B, a thickness th of the 3D structure suspended on the substrate is in a range of less than 1 micron (μm, 1000 nm).

According to one embodiment, a method is described for forming a 3D structure having a continuous metallic material. In one approach, a method is described of nucleation of alpha-phase tantalum (Ta) on a polymer surface using a thin nucleation-promoting material before deposition of Ta, and this process is used to template complex structures of alpha-phase Ta. The technique described herein allows for complex topographies of tantalum (Ta) films. Methods are described that provide local verification that the alpha-phase has been formed at a local level. Methods are described herein that determine formation of the alpha-phase using either resistance measurements or electron microscopy.

In one example of an embodiment, metal airbridges are formed. Such structures are commonly used in superconducting qubit circuits to allow dissipation-less conduction channels to cross on the surface of a chip. A nucleated alpha-phase tantalum airbridges may be formed as follows.

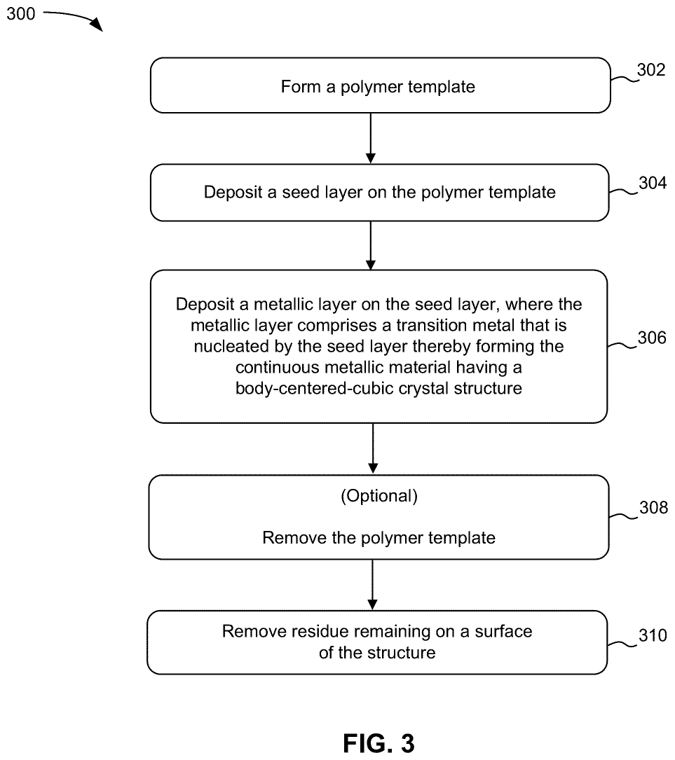

FIG. 3 illustrates a method 300 for forming a three-dimensional (3D) structure comprised of a continuous metallic material having an alpha-phase crystal structure, in accordance with one embodiment. As an option, the present method 300 may be implemented to construct structures such as those shown in the other FIGS. described herein. Of course, however, this method 300 and others presented herein may be used to form structures for a wide variety of devices and/or purposes which may or may not be related to the illustrative embodiments listed herein. Further, the methods presented herein may be carried out in any desired environment. Moreover, greater or fewer operations than those shown in FIG. 3 may be included in method 300, according to various aspects. It should also be noted that any of the aforementioned features may be used in any of the embodiments described in accordance with the various methods.

A method 300 of forming a 3D structure of low loss material may begin with forming a polymer template. Operation 302 includes forming a polymer template. The polymer template may have an arbitrary 3D shape that defines the desired 3D structure. In one approach, the polymer template is a predefined arbitrary shape. In one approach, a polymer template is formed in an arbitrary shape. In various approaches, the polymer template may include one or more photoresist materials. In one approach, the polymer template may be obtained commercially.

Operation 302 includes deposition of the metallic layers includes operation 304 of depositing a seed layer on the polymer template. The seed layer may be deposited on the exposed surfaces of the polymer template. The seed layer may include a metal such as titanium, niobium, aluminum, etc. The seed layer is a nucleation layer. In one approach, a very thin nucleation layer of a seed layer, e.g., a metal such as niobium (Nb), may be deposited first on the polymer photoresist.

Following deposition of the seed layer, operation 306 includes depositing a metallic layer on the seed layer thereby forming a 3D structure comprising a continuous metallic material. The metallic layer includes a transition metal that is nucleated by the seed layer thereby forming the continuous metallic material having a body-centered-cubic (bcc) crystal structure. In various approaches, the deposition of the seed layer and the metallic layer preferably occur in quick succession, e.g., with less than 30 seconds between depositions. Preferably, the depositions occur in the absence of air (e.g., without exposure to air). In preferred approaches, the seed layer and the metallic layer may be deposited at room temperature.

In preferred approaches, a thickness of the deposited seed layer may be in a range of greater than about 1 to less than about 5 nanometers (nm) on the mask layer and exposed regions of the substrate including the portions of the scaffold structure. In various approaches, the transition metal of the seed layer may be any metal that is capable of nucleating tantalum. In one approach, the transition metal of the seed layer is niobium (Nb). In a preferred approach, the metallic layer deposited on the seed layer includes tantalum. The seed layer of Nb functions as a nucleation layer to precipitate the growth of the favorable tantalum phase on a polymer surface.

According to one example, a thin layer of Nb allows the room temperature (RT) nucleation of tantalum (Ta), specifically Ta having a bcc crystal structure (α-Ta). In preferred approaches, the metallic layer includes essentially tantalum (Ta). It is generally well known that an extremely thin seed layer having a thickness of less than 0.50 nm of Nb as seed metal may induce a mixed phase of Ta deposited onto the Nb, whereas an Nb layer having a thickness of 1 nm or greater causes a layer of Ta to grow as essentially 100% alpha-phase Ta (e.g., bcc crystal structure). Thus, a Nb layer having thickness of 2 nm may be considered an excess amount of Nb to precipitate the alpha-phase of Ta. In one approach, a thickness of the Nb layer may be greater than 2 nm, however, a greater thickness of Nb may not affect the essentially uniform alpha-phase of the Ta layer, however, a greater thickness of Nb may adversely affect the advantages of having a circuit that is comprised mostly of Ta.

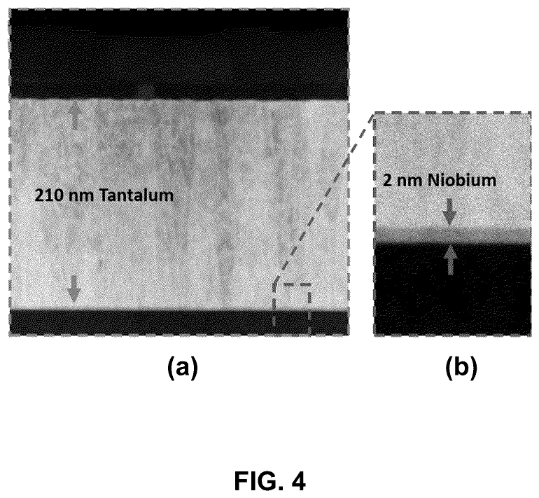

FIG. 4 depicts SEM images of a Nb nucleated Ta layer. Part (a) illustrates a nucleated Ta layer on a Nb layer. Part (b) is a magnified view of the Nb layer relative to the Ta layer. The Ta is sputtered onto a thin layer of Nb layer. The Ta is most stable in the alpha-phase and, thus, a thin layer of Nb initiates the nucleation of the deposited Ta to crystalize in the stable alpha-phase.

Moreover, the method includes a surprising approach that nucleation of Ta on Nb results in formation of a bcc phase on an organic substrate that thereby allows formation of suspended structures comprised of a low loss superconductor. Formation of the grain structure with the two layers (first with the seed layer, e.g., Nb, and second with the Ta layer) is essential for the formation of the alpha-phase of the Ta, and, thus, it was surprising that bombardment of the soft, organic substrate by the plasma and metal vapor environment inherent to the technique of magnetron sputtering did not inhibit the formation of bcc crystallites of Nb and, moreover, a continuous, few nanometer-thick film of those crystallites. A continuous metallic film is absent of cracks having a width greater than 2 nm. The polymer photoresist layer serves as a sufficient scaffold for forming a desired crystal phase of the Ta in the shape of an airbridge.

In an exemplary approach, the metallic layer is preferably tantalum (Ta). The oxides of Ta that form on the circuit often have lower loss when microwaves pass through them than the oxides of Nb, Ti, Al, etc. Moreover, Ta can withstand an acidic etch to clean the entire circuit, wafer, surface, etc. of detrimental residues. Ta is a very hard metal that has a very high melting point of about 3,000° C., and thus its behavior as a metal is not similar to the known metals used in conventional airbridges, such as Al and Ti. In a preferred approach, deposition of a Ta layer onto a Nb layer results in the nucleation of Ta and formation of alpha-phase Ta (α-Ta) in part because there is a near perfect lattice match between the crystal structure of Nb and the crystal structure of Ta.

Moreover, Ta is not known as a metal for deposition via a seed metal layer, such as Nb, on a polymer photoresist. It was surprising that it was clearly evident by microscopy analysis and resistivity analysis that the alpha-phase, e.g., bcc, of Ta forms in the suspended regions above the Nb layer. Without wishing to be bound by any theory, it is believed that the Ta crystals that form on Nb crystals have a consistent, expected crystal formation pattern. In other approaches, Ta may be nucleated and grow bcc crystal structures on functional seed layers such as Ti, Cr, Al, W, TaN, Mo, etc.

In one embodiment, the polymer template may be present where the formed 3D structure has a continuous metallic surface on a polymer template. In another embodiment the polymer template may be removed from the formed 3D structure having a continuous metallic material. Although polymers may be patterned into complex 3D structures, transferring the polymer structure into a metal (e.g., templating) often requires compatibility with an etchant to remove the polymer and any carbonaceous residues.

Tantalum (Ta) is compatible with extremely aggressive etchants of polymers (e.g., a Piranha etch that includes H₂SO₄+H₂O₂). An etching method is preferable to removing polymers via sintering steps since Ta films do not grow in a high quality phase (e.g., the body centered cubic (bcc), alpha-phase) at temperatures compatible with removing polymers. Returning to FIG. 3, optional operation 308 of method 300 includes removing the polymer template. Moreover, excess metals deposited on the polymer template may be removed upon removal of the polymer template. In one approach, the polymer template may be removed using a solvent. For example, the polymer template and extra sputtered metal on portions of the polymer template may be removed using a conventional liftoff technique. The substrate may be soaked in a solvent, e.g., acetone, to remove the polymer photoresist and the metal that is not present in the perimeter of the polymer resist template. The liftoff process may include an additional rinse with a second solvent. For example, the substrate may be rinsed with isopropanol. Following rinsing with the second solvent, the substrate may be dried. For example, the substrate may be dried with nitrogen.

An optional operation 310 of method 300 includes removing residue remaining on the surface of the formed 3D structure and/or a substrate after removal of the polymer template. In one approach, residue may be removed on the surfaces using an acidic etching solution. In one approach, all residues of the polymer template may be completely removed after Piranha etching, while the metallic material of the 3D structure remains intact and demonstrably in the alpha-phase of the crystal, as determined by its resistivity and microscopic morphology.

Residues from a polymer template, such a polymer resist material, that remain on the surfaces may be removed from the substrate using an etching process. The solvents used in the liftoff process in one approach of operation 308 of method 300 are typically not capable of dissolving all compounds present in the polymer template material (e.g., photoresist material). In a preferred approach, a concentrated acid solution may be used as an etching solution to remove the polymer resist material from the surfaces, including the deposited metal layers.

In some approaches, following the etching process, the metal 3D structures may be rinsed in deionized water and ultrasonically cleaned in a solvent such as isopropanol. The resulting 3D structure, and substate if present (e.g., wafer), are essentially free of organic residues. A best measure of organic residues may include optical microscopy. In one approach, organic residues that are present on the substate after a liftoff operation may be visibly removed after a piranha treatment (e.g., acid and hydroxide treatment) and ultrasonic treatment. The visible loss of organic residues on the surfaces of the substrate and bridge is sufficient to represent a clean substrate.

The formation of nucleated metallic films on the polymer template includes a metallic layer that is deposited to thickness that is sufficient for the liftoff process. In one approach, the deposited metallic layer may have a thickness in a range of greater than 100 nm to less than about 500 nm. For example, in a preferred approach, 200 nm of Ta is deposited onto 2 nm of Nb. Moreover, the thickness of α-Ta layers in structures such as other qubit structures of the circuit is typically 200 nm. The thickness of α-Ta in formed 3D structures is predominantly defined by etching parameters since some formed 3D structures may not typically include resist material, and thus liftoff parameters may not be considered.

According to one embodiment, a method includes formation of alpha-phase tantalum airbridge structures that withstand piranha etching so that organic residues may be thoroughly eliminated from the surface. In one approach, forming a metallic airbridge may include forming a polymer template for fabricating a suspended structure on a substrate. Forming the polymer template may include operations that form a scaffold for forming a suspended 3D structure on a substrate.

In one approach, forming a polymer template may begin with forming a first layer comprising a first polymer material on a surface of a substrate. The polymer material may be a photoresist material. The photoresist material may be obtained commercially, for example, photoresist AZ1518 (Merck kGaA, Darnstadt Germany). The substrate may be the material of the circuit, for example, the substrate may be a wafer. A first layer of resist may be spun to a thickness for patterning into a shape for a template scaffold structure. The first layer may function as a scaffold structure. A thickness of the first layers may be determined according to the desired height and contours of the resulting 3D structure. In some approaches, the thickness of the scaffold structure may be in a range of greater than 1 μm up to 50 μm.

In one approach, a scaffold structure may be defined from the first layer. In one approach, the scaffold structure may be defined by patterning the first layer via conventional techniques. For example, a patterning technique may include exposing photoresist to define a template scaffold structure and removing portions of the first layer that are not part of the scaffold structure. The scaffold structure may have edges.

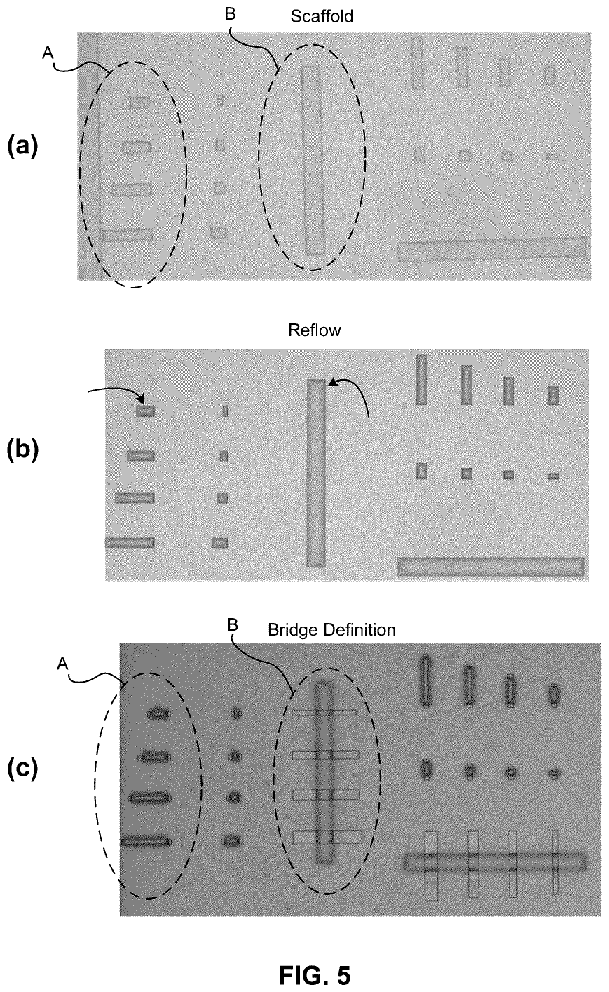

FIG. 5 illustrates an example forming a suspended 3D structure, such as of forming an airbridge using a template having the layers of polymer material. Part (a) of FIG. 5 shows the formation and definition of scaffold structures for defining an arched contour of the resulting bridge. An individual scaffold structure may be formed for each bridge, as shown in the circle A. A scaffold structure may be formed for forming multiple bridges, as shown in circle B. The lengths of the first layers (e.g., each rectangle) may be formed in various sizes, from greater than 5 μm up to mm lengths (e.g., for forming a scaffold structure used for forming multiple bridges as shown in circle B).

In one approach of forming the polymer template, the first layer may be heated to a temperature effective to round the edges of the scaffold structure to some extent. In one approach, a patterned resist layer may be heated in order to round corners of the formed shape, e.g., the scaffold structure. In some approaches, the patterned resist layer may be heated to a temperature below the melting point of the polymer. For example, the temperature may be in a range of greater than room temperature up to 200° C.

For example, a patterned resist layer in a shape of a rectangle may be heated to round sharp corners of the rectangle. As illustrated in the example of FIG. 5, part (b) shows the reflow of the scaffold structures by heating the structures to a temperature of 140° C. The edges of the scaffold structure (designated by the arrow) are rounded.

In one approach, forming a polymer template having a scaffold structure may include adding a second layer of the same polymer material as the polymer material for forming the scaffold structure. In another approach, the polymer material for forming the scaffold may be different than the polymer material for forming the second layer. For example, the polymer material of the second layer is a second photoresist material that is different than the photoresist material of the first layer (e.g., scaffold structure). In one approach, the photoresist may be a positive photoresist material. In another approach, the photoresist material may be a negative photoresist material.

The second layer may be patterned to define a mask having a window that defines a perimeter of a 3D structure. In one approach, the window may have a predefined shape. The window may be configured to expose a portion of the scaffold structure and portions of the substrate. In one approach, the mask is formed using conventional techniques of patterning a photoresist material using lithography.

In various approaches, the predefined shape of the patterns of the mask (e.g., the window) may define the perimeter of the 3D structure where the predefined shape of the window exposes a portion of the scaffold structure and portions of the substrate. The predefined shape of the window may have a shape that is complementary to the contour of the scaffold structure. In one approach, the predefined shape is rectangular. In one example, the predefined shape is a rectangle window that defines a perimeter of a bridge, where the rectangular window exposes a portion of the scaffold structure and portions of the scaffold. The patterned window of the second layer (e.g., mask) may define a perimeter of the bridge-like structure; and the contour of the bridge is defined by the shape of the scaffold structure. In another example, the predefined shape of the patterned window is circular that may define a perimeter of a suspended drum-like structure. In yet another example, the predefined shape of the patterned window is triangular that may define a perimeter of a suspended tent-like structure. These examples are not meant to be limit the type of predefined shape of the patterned window of the mask in any way.

Preferably, formation of the second layer, e.g., mask layer, forms an undercut in the scaffold structure, this means that when the polymer film is patterned, the pattern is wider where the rectangle is wider at the bottom (e.g., underside of the bridge) than the top. A mask layer having a greater undercut will allow formation of a thicker bridge. A different photoresist polymer for the masking may allow tuning of the undercut and masking of the scaffold. The polymer photoresist material for the scaffold needs to be susceptible to reflow where heating the polymer rounds the scaffold structure to define the contour of the bridge. Alternatively, photoresist material for forming the mask preferably allows the mask to form a bridge having an undercut structure.

In one approach, the method of forming the polymer template may include heating the second layer to a temperature effective for baking the second layer onto the scaffold structure. For example, after patterning the predefined shape of the mask layer, the mask layer may be heated to a temperature for baking the mask layer onto the scaffold structure. In some approaches, the layers of photoresist are heated to a temperature to solidify the second layer. For example, the layers of photoresist may be heated to a temperature in a range of greater than room temperature up to 120° C.

Part (c) of FIG. 5 illustrates the formation of the second layer, i.e., a mask layer, on the scaffold structures. Patterning of the second layer with a predefined rectangular shape defines the perimeter of the bridge. The mask layer may include a plurality of rectangular windows where each rectangular window exposes a portion of the scaffold structure. As shown in circle A, a window in the second layer is defined across an individual scaffold structure where the window extends beyond the scaffold structure at each end exposing a portion of the substrate. As shown in circle B, four windows define four respective bridges to be formed across a common scaffold structure. Each window extends beyond each edge of the scaffold structure to expose portions of the substrate on opposite sides of the scaffold structure.

Following formation of the polymer resist template, metal layers are deposited onto the polymer resist template for forming a metal structure having the contour defined by the scaffold structure and a perimeter defined by the windows of the second layer of resist. of which the second layer mask includes the second layer resist and exposed portions of the substate and the scaffold structure that are open to the deposition environment via the window in the second layer. In one approach, metal layers may be deposited using a conventional magnetron sputtering process.

In one approach, a thickness of the metallic layer, e.g., α-Ta, may be limited by the undercut of the masked scaffold. In one example of forming an airbridge, preferably, the layer of deposited Ta detaches from the surface of the substrate at the scaffold in order to form a bridge structure of Ta. A space is defined by the scaffold structure between the substrate and the seed layer where the seed layer and the metallic layer are deposited in the shape of an arch above the substrate. The contour of the formed bridge is defined by the scaffold structure. In some approaches, a metallic layer having a thickness greater than 200 nm may form a blanket deposit over the scaffold without any bridge definition, and removal of the metallic layer from the surface of the substrate is difficult. In one approach, a masked scaffold is formed with an undercut definition such that the thickness of the metallic layer is greater than 200 nm.

In some approaches, the seed layer may be removed from the formed 3D structure. In one example of forming an airbridge, the underside of the airbridge that comprises the nucleation layer (e.g., functional seed layer) may be removed from the formed airbridge. In one approach, a Ta airbridge is grown via nucleation on a titanium (Ti) seed layer, and although the deposited Ta layer may not form a more uniform alpha-phase Ta layer, the Ti layer may be more easily removed from the airbridge (e.g., the Ti layer may be a sacrificial layer etched by an acidic etching solution) leaving clean surfaces on the Ta airbridge (e.g., above and below the airbridge).

In one example of forming an airbridge, a Piranha bath that includes a solution of sulfuric acid and hydrogen peroxide is used to submerge the wafer having the formed metallic airbridges. In some approaches, the wafer may be submerged in the acid etching bath for one hour. In some approaches, the etching process may remove the nucleation layer (e.g., Nb layer) from the airbridge leaving the airbridge comprised of essentially α-Ta. A strong acid etching solution does not affect the crystal phase of the Ta layer. The Ta surface of the structure is not etched by the strong acid etching solution. In sharp contrast, titanium (Ti) and aluminum (Al) are susceptible to being etched by treatment with a strong acid etching solution, such as the piranha etch.

In one embodiment, complementary methods are described for determining the crystalline phase of templated structures, as described herein. For example, the correct crystalline phase of Ta, the bcc or alpha-phase, may be determined after forming the airbridges. These techniques may be applicable to an array of problems within superconducting and conventional microfabrication, and may be immediately relevant for piranha-tolerant airbridge fabrication for superconducting microwave devices, such as qubits, microwave kinetic inductance detectors, etc. It has long been known that a thin nucleation layer of various metals will precipitate the bcc phase on various inorganic surfaces. However, there has not been clear evidence that metals will precipitate the bcc phase on organic surfaces, such as a photoresist polymer substrate. Analysis of the resistivity and morphology of the deposited metallic phase may provide the evidence that deposition of a metallic layer on a seed nucleated layer precipitates the bcc phase on an inorganic surface (a wafer) and an organic surface (photoresist scaffold). As described herein, deposition of Ta on a thin Nb layer results in the nucleation of the alpha-phase of Ta on a polymer surface at room temperature, allowing for the formation of tuned predefined 3D structures.

In one approach, the crystalline phase of the Ta on the surface of the metallic structures can be very clearly determined by simply measuring the conductivity of the airbridges. A method is described that determines the crystalline phase of the templated structures formed on a wafer, e.g., Ta airbridges. A resistivity of the wafer including the templated structure may be measured and the resulting resistivity may be compared to the conductivity of alpha-phase Ta and beta-phase Ta. The resistivity assessment of the wafer may include measuring the conductivity of the templated structure. For example, the resistivity of the wafer may include merely measuring the conductivity of the formed Ta airbridges. In a preferred approach, a resistance measurement of the formed 3D structure provides a definitive test for the crystalline quality of the airbridge.

In another approach, using X-ray diffraction analysis, the surface morphology of the nucleated Ta films correlates to the crystalline phase of the deposited Ta. The surface morphology of nucleated tantalum films may correlate to the crystalline phase, as determined by x-ray diffraction. By inspecting nucleated tantalum structures in an SEM, it is straightforward to determine whether they are alpha-phase or beta-phase according to the length scale of their crystal structures, with crystal grains larger than 20 nm being strongly correlated with alpha-phase growth.

In summary, a method is described for forming very widely controllable 3D metal structures by growing alpha-phase tantalum using a thin nucleation layer on a polymer template structure. The use of tantalum permits chemical compatibility with even the most aggressive techniques for removing the polymer template. The formation of alpha-phase tantalum gives the resulting structures added structural integrity and improved electrical properties, such as reduced conductivity and increased superconducting critical temperature.

### Experiments

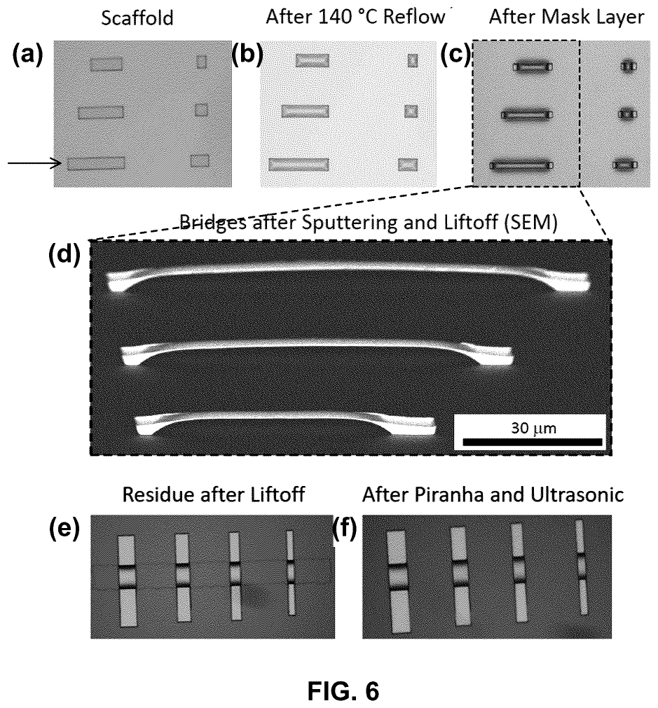

FIG. 6 depicts a series of images that illustrate the operations involved in formation of nucleated tantalum airbridges. Parts (a), (b), and (c) depict an optical microscope images of a top down view of the first steps of forming a series of airbridges. First, a template structure was formed on a wafer (e.g., a substrate) using two successive exposures of lithographically patterned photoresist (AZ1518). The first layer of resist was spun to a thickness of 2-3 μm, baked at 90° C. and patterned into rectangular shapes having various sizes (e.g., the lower left, indicated by→, having a length of 105 μm) defining the “scaffold” of the bridge photoresist material (part (a)). The sample was then heated (e.g., reflowed) at 140° C. for five minutes to round the sharp corners of the rectangles to form a contour of the structurally favorable arch, as seen in part (b). The scaffold has the shape of a domed rectangle on the substrate.

A mask layer, e.g., a second photoresist layer, of AZ1518 was spun and exposed to form the rectangular windows defining the perimeters of the bridges as shown in the optical image in part (c). The scaffold structures define the contour of the bridges. The second layer of photoresist film is a mask that exposes a portion of the domed scaffold of part (b) and extended portions of the substrate on opposite sides of the scaffold structure. A thickness of the second layer may be in a range of 2 to 3 μm.

The deposition procedure was a magnetron sputtering process where 2 nm of Nb was deposited at 300 W from a 3 inch magnetron source, followed by 200 nm of Ta. The two depositions took place in quick succession (<30 s between steps) without exposure to air. Both Nb and Ta were deposited at a rate of 0.2 nm/s in 0.4 Pa of ultra-high purity argon (Ar) (300 W, 150 mm from substrate, from a base pressure of 5×10−8 Torr).

The three scaffolds as indicated in part (c) correspond to the three airbridges depicted in perspective view in the electron microscope image of part (d). Part (d) depicts the airbridges formed after deposition of niobium (Nb) and then tantalum (Ta) onto the masked scaffolds formed in part (c). The electron microscope image depicted in part (d) shows the airbridge structures formed after the operations of sputtering of the Nb and Ta and the liftoff operation which removes the mask layer, the photoresist scaffold, and extraneous metal sputtered on the mask layer. The image has been captured at an angle to clearly show that the bridges have been properly formed and the scaffold fully removed.

Parts (e) and (f) depict optical microscope images of a top down view of the formed airbridges. Part (e) of is an image of the airbridges and the carbon residues from the removed photoresist material; these stubborn carbon residues remain on the substrate after the liftoff operation and are present in the areas surrounding the bridges on the surface of the substrate. The image of part (e) shows a top down view of a set of airbridges in vertical orientation that have a different structure than the airbridges shown in arts (a)-(d) where the airbridges are shown in a horizontal orientation. The airbridges shown in parts (e) and (f) show the shadow of the bridge arch (two dark lines) and each bridge has longer “feet” relative to the arch (as compared to the airbridges of parts (a)-(d) that have smaller feet and a longer bridge arch).

As mentioned above, the liftoff process removes the polymer photoresist material and excess metal, however, inevitably, residues remain on the substrate. The liftoff process includes soaking the wafers with the templated Ta films in acetone to remove the metal that was not within the airbridge perimeter (liftoff). After rinsing in isopropanol and drying with nitrogen, the result is as shown in parts (e) and (f). In the image of part (e), a residue on the substrate outlines the perimeter of the scaffold that extends between the four airbridges indicating a common scaffold was used to form the four airbridges on the substrate.

Finally, the wafer with the airbridges are immersed in a fuming Piranha bath (3 parts of concentrated sulfuric acid and 1 part 30 wt. % hydrogen peroxide) for 1 hour. It was then rinsed in deionized water, and ultrasonically cleaned for 1 minute in isopropanol. The image of part (f) shows the residue on the substrate between the airbridges has been removed following a piranha etch and ultrasonication in isopropanol. All traces of residues were eliminated, while the bridge structures remained completely intact. The surfaces of the substrate and bridge are demonstrated to be clean, and particularly free from organic residues.

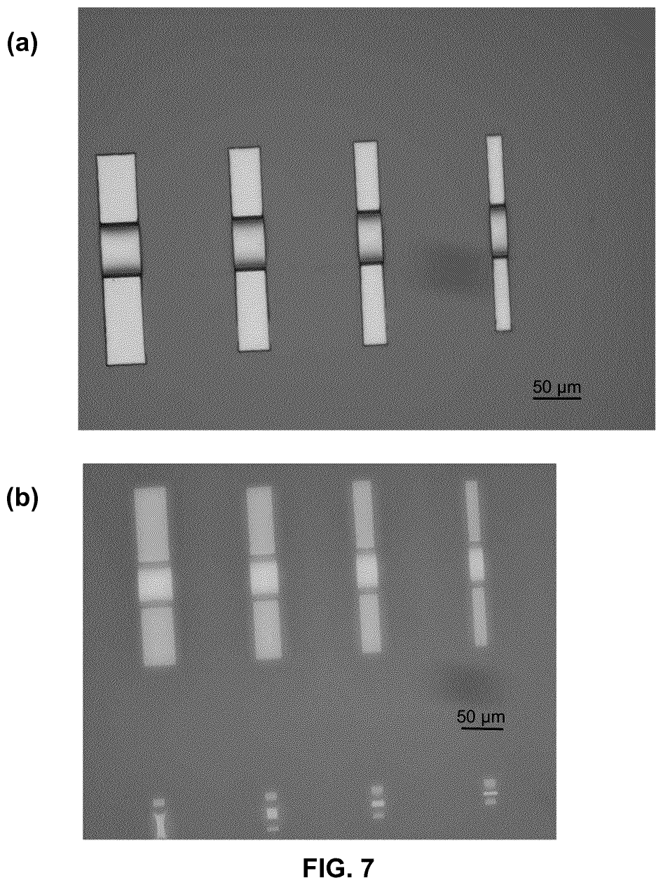

FIG. 7 shows images of formed airbridges without residues after a piranha etch and ultrasonic treatment. Part (a) depicts a top down view of four airbridges. Part (b) depicts a bottom up view formed airbridges without residues. The airbridges are formed in different sizes, and none of the structures or substrate have residues.

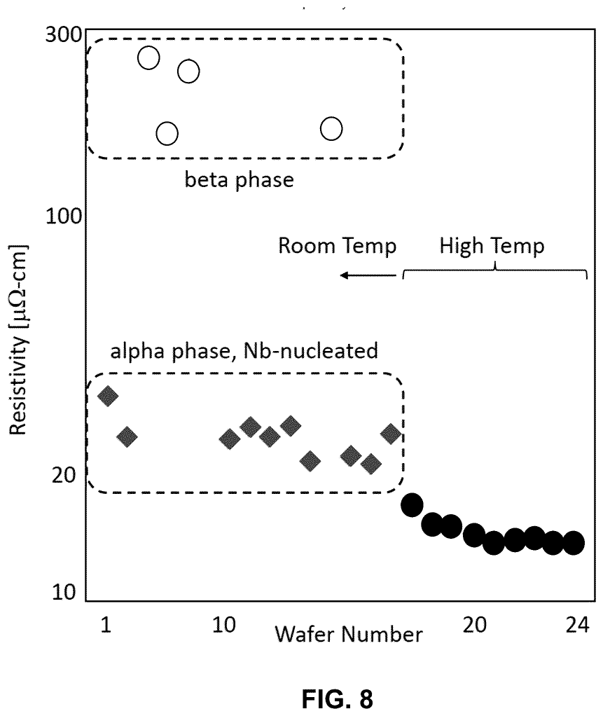

As illustrated in the example shown in FIG. 8, the crystalline phase of the airbridges may be determined from film resistivity. The resistivity of the Ta films demonstrated an order of magnitude according to whether it is in the alpha (♦) phase or the beta (∘) phase. This finding is consistent with known resistivity of the crystalline phases of Ta. As a result, the local phase of the tantalum in templated structures may readily be verified by measuring the resistance of the Ta bridge. The alpha-phase Ta of FIG. 8 are represented by Ta nucleated by Nb (♦) and Ta grown at higher temperatures (●). This technique was applied to airbridges similar to airbridges formed in FIG. 6. The resistivity of the suspended segments was 29±1 μOhm-cm, which was only slightly higher than the resistivity of segments entirely on the wafer surface, which were 23±1 μOhm-cm. Therefore, resistance measurements provide a clear and simple test for the crystalline quality of the bridges.

As illustrated in one example in FIG. 9, crystalline phase of the Nb-nucleated tantalum may be determined from film morphology. Part (a) illustrates a comparison of Ta films grown by various conditions (1) 200 nm Ta grown on sapphire substrate at 500° C. (∘), (2) 200 nm Ta on 2 nm Nb on sapphire substrate at RT (●), (3) 200 nm Ta on 2 nm Nb on silicon substrate, (▪), and (4) 200 nm Ta on silicon substrate at 400° C. (no symbol). Electron microscope inspection may be used to determine the crystal phase of the tantalum on a finer scale. The electron microscopy (SEM) of films grown under various conditions may be correlated with x-ray diffraction. Part (b) shows the Ta filaments of sample (1), part (c) shows the Ta filaments of sample (2), and part (d) shows the Ta filaments of sample (3); and each of these images show elongated filaments representative of alpha-phase crystals adjacent an image of the X-ray diffraction spectroscopy of each sample. In sharp contrast, part (e) shows the Ta filaments of sample (4) formed at a lower temperature and no Nb nucleation thereby representing a mixture of beta-phase crystals and alpha-phase filaments of Ta. The filaments shown in the image of part (e) are not elongated. Thus, these images show there is a straightforward method to determine the phase locally from a given sample by analysis of the surface of the Ta film using SEM.

The images shown in parts (c) and (d) show that nucleation of the Ta with Nb allows the size of the Ta alpha crystal grains are different compared to the Ta alpha crystal grains formed with conventional high temperature treatment as shown in part (b). The performance of the Ta films may be a function of the size of the alpha crystal grains. Moreover, a comparison of the hardness of the substrate such as sapphire in samples (1) and (2) generated higher counts of alpha-phase Ta compared to silicon in samples (3) and (4), thereby suggesting that the hardness and composition of the substrate and/or layer below the Ta and Nb affects the growth of alpha-phase Ta. It was surprising, thus, that alpha-phase Ta may be grown on Nb that had been deposited directly on polymer photoresist, as described herein.

### In Use

Various aspects of an inventive concept described herein may be used for the formation of airbridges and other 3D structures within superconducting quantum processors. Embodiments described herein include superconducting electronics with minimal polymer contamination. Embodiments described herein include microfabrication of 3D metal structures with little organic residues.

The inventive concepts disclosed herein have been presented by way of example to illustrate the myriad features thereof in a plurality of illustrative scenarios, aspects of an inventive concept, and/or implementations. It should be appreciated that the concepts generally disclosed are to be considered as modular, and may be implemented in any combination, permutation, or synthesis thereof. In addition, any modification, alteration, or equivalent of the presently disclosed features, functions, and concepts that would be appreciated by a person having ordinary skill in the art upon reading the instant descriptions should also be considered within the scope of this disclosure.

While various aspects of an inventive concept have been described above, it should be understood that they have been presented by way of example only, and not limitation. Thus, the breadth and scope of an aspect of an inventive concept of the present invention should not be limited by any of the above-described exemplary aspects of an inventive concept but should be defined only in accordance with the following claims and their equivalents.

What is claimed is:

1. A product, comprising:
a three-dimensional structure comprising a continuous metallic material,
wherein the continuous metallic material comprises at least two layers, a first layer of the at least two layers comprising a metal and a second layer of the at least two layers comprising a transition metal having a body-centered-cubic crystal structure.

2. The product as recited in claim 1, wherein the metal is selected from a group consisting of: titanium, niobium, and aluminum.

3. The product as recited in claim 1, wherein the transition metal consists essentially of tantalum.

4. The product as recited in claim 1, wherein the structure is essentially free of carbon residue.

5. The product as recited in claim 1, comprising a substrate, wherein at least one end of the structure is positioned on a surface of the substrate.

6. The product as recited in claim 5, wherein the structure has a portion suspended on the substrate.

7. The product as recited in claim 5, wherein the substrate is essentially free of carbon residue.

8. The product as recited in claim 5, wherein the three-dimensional structure is a bridge, wherein the bridge has a portion having an arched shape between opposite ends of the structure, and the ends of the structure being positioned on the surface of the substrate.

9. The product as recited in claim 1, wherein the three-dimensional structure has a thickness in a range of greater than 100 nanometers to less than about 2 microns.

10. A method of forming a three-dimensional structure comprising a continuous metallic material, the method comprising:
forming a polymer template;
depositing a seed layer on the polymer template; and
depositing a metallic layer on the seed layer, wherein the metallic layer comprises a transition metal that is nucleated by the seed layer thereby forming the continuous metallic material having a body-centered-cubic crystal structure.

11. The method as recited in claim 10, wherein the seed layer includes a metal selected from the group consisting of: titanium, niobium, and aluminum.

12. The method as recited in claim 10, wherein the transition metal consists essentially of tantalum.

13. The method as recited in claim 10, wherein the seed layer and the metallic layer are deposited at room temperature.

14. The method as recited in claim 10, wherein the seed layer has a thickness in a range of greater than about 1 nanometer to less than about 5 nanometers.

15. The method as recited in claim 10, wherein the metallic layer has a thickness in a range of greater than 100 nanometers to less than about 500 nanometers.

16. The method as recited in claim 10, further comprising, removing the polymer template.

17. The method as recited in claim 16, comprising, removing residue remaining on a surface of the structure.

18. The method as recited in claim 10, wherein forming the polymer template comprises:
forming a first layer of a first polymer material on a substrate, wherein the first layer is configured as a scaffold structure,
forming a second layer comprising a second polymer material on the scaffold structure, and,
patterning the second layer to define a mask having a window of a predefined shape, wherein the window defines a perimeter of the three-dimensional structure, wherein the window exposes a portion of the scaffold structure and portions of the substrate.

19. The method as recited in claim 18, further comprising:
heating the first layer to a first temperature effective to round edges of the scaffold structure.

20. The method as recited in claim 18, wherein a space is defined by the scaffold structure between the substrate and the seed layer.

21. The method as recited in claim 18, wherein the second polymer material is the same as the first polymer material.

22. The method as recited in claim 18, wherein the second polymer material is different than the first polymer material.

23. The method as recited in claim 18, further comprising,
heating the second layer to a second temperature effective for baking the second layer onto the scaffold structure.

24. The method as recited in claim 18, wherein the formed three-dimensional structure is a bridge,
wherein the patterning of the second layer defines a perimeter of the bridge.

25. The method as recited in claim 24, wherein a contour of the bridge is defined by a shape of the scaffold structure.

26. The method as recited in claim 24, wherein the predefined shape of the window is rectangular.
